(19) United States
(12) Patent Application Publication
(10) Pub. No.: US 2019/0296161 A1
(43) Pub. Date: Sep. 26, 2019

(54) METHOD OF FORMING ELECTRODE PATTERN FOR SOLAR CELL, ELECTRODE MANUFACTURED USING THE SAME AND SOLAR CELL

(71) Applicant: SAMSUNG SDI CO., LTD., Yongin-si, Gyeonggi-do (KR)

(72) Inventors: Sungil MOON, Suwon-si, Gyeonggi-do (KR); Hyungseok PARK, Suwon-si, Gyeonggi-do (KR); Jinwoo CHOI, Suwon-si, Gyeonggi-do (KR)

(21) Appl. No.: 16/304,397

(22) PCT Filed: Apr. 17, 2017
(86) PCT No.: PCT/KR2017/004085

§ 371 Date: Nov. 26, 2018

(30) Foreign Application Priority Data
Sep. 21, 2016 (KR) 10-2016-0120646

(51) Int. Cl. H01L 31/0224

(52) U.S. Cl. CPC H01L 31/022425

(57) ABSTRACT

Provided are a method of forming an electrode pattern for a solar cell, an electrode manufactured using the same, and a solar cell. The method of forming an electrode pattern for a solar cell includes preparing a composition for forming a solar cell electrode including a conductive powder, a glass frit, an organic binder, and a solvent, and coating the composition for forming a solar cell electrode on a screen mask with an organic layer followed by drying and firing the same, wherein a difference of water contact angles of the composition for forming a solar cell electrode and the screen mask with the organic layer ranges from 40 degrees to 60 degrees.

### TECHNICAL FIELD

A method of forming an electrode pattern for a solar cell, an electrode manufactured using the same, and a solar cell are disclosed.

### BACKGROUND ART

Solar cells generate electrical energy using the photovoltaic effect of a p-n junction which converts photons of sunlight into electricity. In the solar cell, front and rear electrodes are formed on front and rear surfaces of a semiconductor substrate (semiconductor wafer) with the p-n junction, respectively. A photovoltaic effect of the p-n junction is induced by sunlight entering the substrate and electrons generated by the photovoltaic effect of the p-n junction provide an electric current to the outside through the electrodes.

The electrodes of the solar cell may be formed with predetermined patterns on a surface of a substrate by coating an electrode composition on a screen mask followed by drying and firing process.

Conversion efficiency of a solar cell is known to be improved by increasing a shortcut current (I_{sc}) by coating an organic material on a screen mask, adjusting pattern line widths to be smaller, and thus forming fine lines. However, a method of reducing line widths of the electrode pattern with the screen mask with an organic layer may lead to increasing series resistance (Rs) and deteriorating continuous printability of a fine pattern.

### DISCLOSURE OF INVENTION

### Technical Problem

An embodiment provides a method of forming an electrode pattern for a solar cell which is capable of improving printability, particularly continuous printability.

Another embodiment provides an electrode manufactured according to the method.

Yet another embodiment provides a solar cell including the electrode.

### Solution to Problem

According to one embodiment, a method of forming an electrode pattern for a solar cell includes preparing a composition for forming a solar cell electrode including a conductive powder, a glass frit, an organic binder, and a solvent, and

coating the composition for forming a solar cell electrode on a screen mask with an organic layer followed by drying and firing the composition for forming the solar cell electrode,

wherein a difference of water contact angles of the composition for forming a solar cell electrode and the screen mask with the organic layer ranges from 40 degrees to 60 degrees.

The difference of water contact angles of the composition for forming a solar cell electrode and the screen mask with the organic layer may range from 50 degrees to 55 degrees.

The water contact angle of the composition for forming a solar cell electrode may be less than or equal to 30 degrees.

The water contact angle of the screen mask with the organic layer may be greater than or equal to 70 degrees.

The composition for forming a solar cell electrode may include 60 to 95 wt % of the conductive powder; 0.5 to 20 wt % of the glass frit; 1 to 20 wt % of the organic binder, and a balance amount of the solvent.

The organic binder may include a (meth)acrylate-based resin or a cellulose-based resin.

The composition for forming a solar cell electrode may further include at least one selected from a hydrophobizing agent, a surface-treatment agent, a dispersing agent, a thixotropic agent, a viscosity stabilizer, an antifoaming agent, a pigment, an ultraviolet (UV) stabilizer, an antioxidant, and a coupling agent.

Another embodiment provides an electrode manufactured using the method of forming an electrode pattern for a solar cell.

Another embodiment provides a solar cell including the electrode.

### Advantageous Effects of Invention

The method of forming an electrode pattern for a solar cell may provide a high resolution finely patterned electrode and may improve print characteristics, particularly continuous printability. An electrode manufactured according to the method may improve efficiency of a solar cell.

### BRIEF DESCRIPTION OF DRAWINGS

FIG. 1 is a schematic view showing a coating process of a composition for forming a solar cell electrode on a screen mask.

FIG. 2 is a schematic view showing the structure of a solar cell according to one embodiment.

### BEST MODE FOR CARRYING OUT THE INVENTION

Hereinafter, the present invention will be described more fully hereinafter with reference to the accompanying drawings, in which example embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

A method of forming an electrode pattern for a solar cell according to an embodiment includes preparing a composition for forming a solar cell electrode including a conductive powder, a glass frit, an organic binder, and a solvent, and

coating the composition for forming a solar cell electrode on a screen mask with an organic layer followed by drying and firing the composition for forming the solar cell electrode, and

wherein a difference of water contact angles of the composition for forming a solar cell electrode and the screen mask with the organic layer ranges from 40 degrees to 60 degrees.

In the present specification, a water contact angle of the composition for forming a solar cell electrode is obtained by coating the composition for forming a solar cell electrode on a polymer film at room temperature (20° C. to 25° C.) with a squeegee to form a film, dropping distilled water on the surface of the formed film with a micro syringe, and measuring an angle between a tangent of the water and the surface of the film at a liquid-solid-gas junction with a contact angle-measuring device (Phoenix 300 Plus, SEO).

The polymer film may be a polyethylene terephthalate (PET) film and the like but is not limited thereto.

A water contact angle of the screen mask with the organic layer is obtained by dropping distilled water on the surface of the organic layer of the screen mask and then, measuring an a tangent of the distilled water with the surface of the organic layer at the liquid-solid-gas junction with a contact angle-measuring device (Phoenix 300 Plus).

A difference of the water contact angles of the composition for forming a solar cell electrode and the screen mask with the organic layer may range from 40 degrees to 60 degrees, for example 50 degrees to 60 degrees. When the water contact angle difference is within the range, wettability on the interface of the composition for forming a solar cell electrode with the organic layer of the screen mask may be improved, printability of the composition for forming a solar cell electrode may be improved, and an electrode having a high aspect ratio and a fine pattern may be formed.

The water contact angle of the composition for forming a solar cell electrode may be less than or equal to 30 degrees, for example less than or equal to 20 degrees, and the water contact angle of the screen mask with the organic layer may be greater than or equal to 70 degrees, for example greater than or equal to 75 degrees. Within the ranges, the difference of water contact angles of the composition for forming a solar cell electrode and the screen mask with the organic layer may be easily controlled and printability may be also improved.

First, in the method of forming an electrode pattern for a solar cell, a composition for forming a solar cell electrode satisfying the water contact angle within the ranges is prepared.

The composition for forming a solar cell electrode may include a conductive powder, a glass frit, an organic binder, and a solvent.

The conductive powder may be a metal powder. The metal powder may include at least one metal selected from silver (Ag), gold (Au), palladium (Pd), platinum (Pt), ruthenium (Ru), rhodium (Rh), osmium (Os), iridium (Ir), rhenium (Re), titanium (Ti), niobium (Nb), tantalum (Ta), aluminum (Al), copper (Cu), nickel (Ni), molybdenum (Mo), vanadium (V), zinc (Zn), magnesium (Mg), yttrium (Y), cobalt (Co), zirconium (Zr), iron (Fe), tungsten (W), tin (Sn), chromium (Cr), and manganese (Mn) but is not limited thereto.

The particle size of the conductive powder may be nanometer or micrometer scale. For example, the conductive powder may have a particle size of dozens to several hundred nanometers, or several to dozens of micrometers. In other embodiments, the conductive powder may be a mixture of two or more types of silver powders having different particle sizes.

The conductive powder may have a particle shape of a spherical shape, a sheet-shape, or amorphous. The conductive powder may have an average particle diameter (D50) of 0.1 μm to 10 μm, for example 0.5 μm to 5 μm. The average particle diameter may be measured using, for example, Model 1064D (CILAS Co., Ltd.) equipment after dispersing the conductive powder in isopropyl alcohol (IPA) at room temperature (about 24° C. to about 25° C.) for 3 minutes via ultrasonication. Within this ranges, contact resistance and line resistance may be lowered.

The conductive powder may be treated to have a hydrophobic surface.

The conductive powder is manufactured in a liquid reduction method, and in general, the conductive powder hydrophobically treated with fatty acid is obtained by dissolving nitric acid in an aqueous solution, adding fatty acid and a phase transition compound thereto, heating and stirring the mixture, filtering and washing a product therefrom, and drying it in a vacuum oven.

The conductive powder may be included in an amount of 60 to 95 wt % based on a total amount 100 wt % of the composition for forming a solar cell electrode. Within the range, deterioration in conversion efficiency due to an increase in resistance may be prevented and hard formation of paste caused by a relative decrease of an organic vehicle may also be prevented. Preferably, it may be included in an amount of 70 to 90 wt %.

The glass frit may serve to enhance adhesion between the conductive powder and the wafer or the substrate and to form silver crystal grains in an emitter region by etching an anti-reflection layer and melting the conductive powder so as to reduce contact resistance during a firing process of the composition for forming a solar cell electrode. Further, during the sintering process, the glass frit may be softened and may decrease the firing temperature.

The glass frit may be one or more of a lead glass frit and a non-lead glass frit which are generally used in a composition for forming an electrode.

The glass frit may include at least one metal element selected from lead (Pb), tellurium (Te), bismuth (Bi), lithium (Li), phosphorus (P), germanium (Ge), gallium (Ga), cerium (Ce), iron (Fe), silicon (Si), zinc (Zn), tungsten (W), magnesium (Mg), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), manganese (Mn), and aluminum (Al).

The glass frit may be prepared from oxides of the metal elements by any suitable method. For example, the metal oxides may be obtained by mixing the oxides of the metal elements in a predetermined ratio, melting the mixture, quenching the resultant, and then pulverizing the quenched product. Mixing may be performed using a ball mill or a planetary mill. The melting may be performed at 700° C. to 1300° C. and the quenching may be performed at room temperature (20° C. to 25° C.). The pulverizing may be performed using a disk mill or a planetary mill without limitation.

The glass frit may have an average particle diameter (D50) of 0.1 μm to 10 μm, and may be present in an amount of 0.5 wt % to 20 wt % based on 100 wt % of the composition for forming a solar cell electrode. Within this range, the glass frit may secure excellent adhesive strength of an electrode while not deteriorating electrical characteristics of an electrode.

The glass frit may have a spherical shape or an amorphous shape. In one embodiment, two different kinds of glass frit having different transition temperatures may be used. For example, a first glass frit having a transition temperature ranging from greater than or equal to 200° C. to less than or equal to 350° C. and a second glass frit having a transition temperature ranging from greater than 350° C. to less than or equal to 550° C. may be mixed in a weight ratio ranging from 1:0.2 to 1:1.

The organic binder may include a (meth)acrylate-based resin or a cellulose-based resin. The (meth)acrylate-based resin or cellulose-based resin may be used without limitation as long as it is a resin used in a composition for forming a solar cell electrode. In addition to the resin, ethylhydroxyethyl cellulose, nitrocellulose, a mixture of ethyl cellulose and a phenolic resin, an alkyd resin, a phenol-based resin, an acrylic acid ester-based resin, a xylene-based resin, a polybutene-based resin, a polyester-based resin, an urea-based resin, a melamine-based resin, a vinyl acetate-based resin, wood rosin, or polymethacrylates of alcohols may be used.

A weight average molecular weight (Mw) of the organic binder may range from 30,000 to 200,000 g/mol, and preferably 40,000 to 150,000 g/mol. When the weight average molecular weight (Mw) is within the range, an excellent effect in term of printability may be obtained.

The organic binder may be included in an amount of 1 to 20 wt %, preferably 2 to 15 wt % based on a total amount 100 wt % of the composition for forming a solar cell electrode. When the organic binder is used within the range, the composition for forming a solar cell electrode may have appropriate viscosity and be prevented from adherence deterioration to the substrate, and may also have high resistance due to unsmooth decomposition of the organic binder during firing and prevent an electrode from being cracked, being opened, having a pin hole, and the like during the firing.

The solvent may include, for example, hexane, toluene, texanol (2,2,4-trimethyl-1,3-pentanediol monoisobutyrate), methylcellosolve, ethylcellosolve, cyclohexanone, butylcellosolve, aliphatic alcohol, butyl carbitol (diethylene glycolmonobutyl ether), dibutylcarbitol (diethylene glycoldibutyl ether), butyl carbitol acetate (diethylene glycolmonobutyl ether acetate), propylene glycolmonomethyl ether, hexylene glycol, terpineol, methylethylketone, benzylalcohol, gammabutyrolactone, and ethyllactate, which may be used alone or in a combination of two or more.

The solvent may be used in a balance amount, for example 1 wt % to 30 wt %, preferably 5 wt % to 15 wt % based on a total amount of the composition for forming a solar cell electrode. Within the range, sufficient adhesion strength between an electrode pattern and a substrate may be improved and excellent continuous printability may be secured.

The composition for forming a solar cell electrode may further include additives as needed, to enhance hydrophobicity, flow properties, process properties, and stability of the composition in addition to the constituent elements. The additives may include a hydrophobizing agent, a surface-treatment agent, a dispersing agent, a thixotropic agent, a viscosity stabilizer, an antifoaming agent, a pigment, an ultraviolet (UV) stabilizer, an antioxidant, a coupling agent, which may be used alone or as mixtures of two or more.

Examples of the hydrophobizing agent may be chlorosilanes such as methylchlorosilane, ethyl chlorosilane, propyl chlorosilane, vinyl chlorosilane, phenyl chlorosilane, and the like; silicone polymers such as dimethylpolysiloxane, silicone oil and the like; alkoxysilanes such as methyl methoxysilane, methyl ethoxysilane, ethyl methoxysilane, vinyl methoxysilane, phenyl methoxysilane, and the like; fluorinating agents such as diethyl aminotrimethylsilane, carbonylfluoride, hydrogen fluoride, and the like.

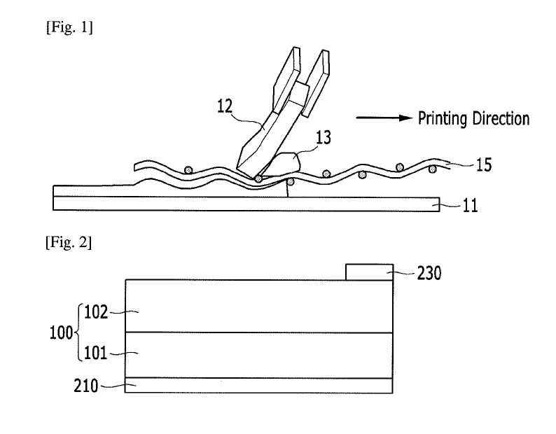

These additives may be used in an amount of 0.1 wt % to 5 wt % based on a total amount 100 wt % of the composition for forming a solar cell electrode but the amount may be changed as desired. The amount of the additives may be selected considering hydrophobicity, print characteristics, dispersibility, and storage stability of the composition for forming a solar cell electrode. The composition for forming a solar cell electrode is coated on a screen mask with an organic layer and then, dried and fired. The coating is described referring to FIG. 1. FIG. 1 is a schematic view showing a coating process of a composition for forming a solar cell electrode on a screen mask. As shown in FIG. 1, the composition 13 for forming a solar cell electrode is coated on a substrate 11 by extruding the composition 13 for forming a solar cell electrode with a squeegee 12 while supplied on the screen mask 15 and discharging the composition 13 for forming a solar cell electrode among meshes of a screen mask 15. An organic layer is coated on the surface of the screen mask 15, and herein, a water contact angle of the organic layer and a water contact angle of the composition for forming a solar cell electrode may be adjusted to have a difference in a range of 40 degrees to 60 degrees, for example, 50 degrees to 55 degrees. When the water contact angles have a difference within the range, the composition 13 for forming a solar cell electrode may be well separated from the screen mask 15, and thus continuous printability may be improved.

The composition for forming a solar cell electrode is manufactured into a patterned electrode through drying and firing processes. The drying process may be performed at a temperature of 200° C. to 400° C. temperature for around 10 seconds to 60 seconds and the firing process may be performed at a temperature of 400° C. to 980° C., and preferably 700° C. to 980° C. for about 30 seconds to 210 seconds.

According to another embodiment, a solar cell including the patterned electrode is provided.

Referring to FIG. 2, a solar cell according to an embodiment is described. FIG. 2 is a schematic view showing the structure of a solar cell according to one embodiment.

Referring to FIG. 2, a solar cell includes a p layer 101 (or n layer) and an n layer 102 (or p layer) as an emitter, and a rear electrode 210 and a front electrode 230 on a substrate 100.

### Mode for the Invention

Hereinafter, the present disclosure is illustrated in more detail with reference to examples. However, these examples are exemplary, and the present disclosure is not limited thereto.

Preparation of Composition for Forming Solar Cell Electrode

### Example 1

A composition for forming a solar cell electrode was prepared by sufficiently dissolving 0.5 wt % of an organic binder (Mw=50,000 g/mol, STD4, Dow Chemical Company) in 7.5 wt % of butylcarbitol (Dow Chemical) as a solvent at 60° C., adding 88.5 wt % of spherical silver powders having an average particle diameter of 2.0 μm (AG-5-11F, Dowa Hightech Co. Ltd.), 3 wt % of Bi—Te-based non-lead glass frit powders having an average particle diameter of 1.0 μm (ABT-1, Asahi Glass Co., Ltd.), 0.2 wt % of a dispersing agent (BYK-102, BYK-Chemie), and 0.3 wt % of a thixotropic agent (Thixatrol ST, Elementis Co.) thereto, and dispersing them with a three roll mill. The composition for forming a solar cell electrode was coated on a polyethylene terephthalate (PET) film, and a water contact angle was 15° when measured by using a contact angle-measuring device (Phoenix 300 plus, SEO (Surface Electro Optics) after dropping a distilled water thereon.

### Example 2

A composition for forming a solar cell electrode according to Example 2 was prepared according to the same method as Example 1 except for using 7.5 wt % of butylcarbitol acetate (Dow Chemical) instead of the butylcarbitol (Dow Chemical) as a solvent, wherein a water contact angle was 20° when measured according to the same method as Example 1.

### Example 3

A composition for forming a solar cell electrode according to Example 3 was prepared according to the same method as Example 1 except for using 7.5 wt % of butylcarbitol acetate (Dow Chemical) instead of the butyl carbitol (Dow Chemical) as a solvent and 88.5 wt % of spherical silver powders having an average particle diameter of 2.0 μm (AG-4-8F, Dowa Hightech Co. Ltd.) instead of the spherical silver powders having an average particle diameter of 2.0 μm (AG-5-11F, Dowa Hightech Co. Ltd.), wherein a water contact angle was 30° when measured according to the same method as Example 1.

### Comparative Example 1

A composition for forming a solar cell electrode according to Comparative Example 1 was prepared according to the same method as Example 1 except for using 88.5 wt % of spherical silver powders having an average particle diameter of 2.0 μm (AG-4-8F, Dowa Hightech Co. Ltd.) instead of the spherical silver powders having an average particle diameter of 2.0 μm (AG-5-11F, Dowa Hightech Co. Ltd.), wherein a water contact angle was 44° when measured according to the same method as Example 1.

Evaluation of Fine Pattern

The compositions for forming a solar cell electrode according to Examples 1 to 3 and Comparative Example 1 were respectively screen-printed on the front surface of a poly P-type silicon wafer having a sheet resistance of 90 by using a screen mask (SUS325 type/thickness of emulsion organic layer: 15 μm/line width of finger bar: 35 μm, the number of finger bars: 90; 6-Multi-35 um-90 EA, Samborn Screen) to form electrode patterns and then, dried by using an infrared ray drying furnace.

A water contact angle of the screen mask was measured by using a contact angle-measuring equipment (Phoenix 300 Plus, SEO) after distilled water was dropped on an organic layer of the screen mask. The water contact angle of the screen mask was 70°.

The difference of water contact angles of the composition for forming a solar cell electrode and the screen mask with the organic layer is reported in Table 1.

The line width and thickness of the electrode lines manufactured using of the compositions for forming a solar cell electrode according to Examples 1 to 3 and Comparative Example 1 were measured by using VK equipment (VK9710, Keyence Co.).

The number of open lines was counted by using an electroluminescence (EL) tester (MV Tech Inc.) to examine whether an electrode (a finger bar) was disconnected or not. The results are shown in Table 1.

Evaluation of Efficiency of Solar Cell

An electrode-forming composition including aluminum was printed on the rear surface of a silicon wafer with the fine pattern and dried using an infrared ray drying furnace. Cells obtained in the process was then fired at 400° C. to 950° C. in a belt-type furnace for 40 seconds, manufacturing test cells. Efficiency of the test cells were measured using a solar cell efficiency-measuring equipment (CT-801, manufactured by Pasan). The results are shown in Table 1.

TABLE 1

| | | | | Comparative |
|---|---|---|---|---|
| | Example | Example | Example | Example |
| | 1 | 2 | 3 | 1 |
| Difference of | 55 | 50 | 40 | 26 |
| water contact angle (°) | | | | |
| Line width | 63 | 63 | 61 | 64 |
| after firing (μm) | | | | |
| Thickness | 18 | 17 | 15 | 12 |
| after firing (μm) | | | | |
| Aspect ratio | 0.29 | 0.27 | 0.25 | 0.19 |
| (thickness/line width) | | | | |
| Printability | <10 | <10 | <10 | >40 |
| (the number of dis- | | | | |
| connected lines) | | | | |
| Efficiency (%) | 17.39 | 17.34 | 17.20 | 11.56 |

Referring to Table 1, the electrodes formed of the compositions for forming a solar cell electrode having a water contact angle difference from the screen mask with the organic layer within a range of 40 degrees to 60 degrees according to Examples 1 to 3 realized a fine line width, had a high aspect ratio, and showed excellent printability and a low generation rate of a disconnected line compared with the electrode formed of the composition for forming a solar cell electrode having a difference out of the range according to Comparative Example 1. In addition, the test cells respectively including the electrodes manufactured by using the compositions for forming a solar cell electrode according to Examples 1 to 3 showed superbly improved efficiency compared with the test cell including the electrode manufactured by using the composition for forming a solar cell electrode according to Comparative Example 1.

Simple modifications and equivalent arrangements of this invention may be easily embodied by a person having an ordinary skill in this art, but, on the contrary, is intended to cover various modifications and equivalent arrangements included within the spirit and scope of the appended claims.

### DESCRIPTION OF SYMBOLS

11: substrate
12: squeegee
13: composition for forming a solar cell electrode
15: screen mask
100: substrate
101: p layer
102: n layer
210: rear electrode
230: front electrode

1. A method of forming an electrode pattern for a solar cell, comprising
providing a composition that includes a conductive powder, a glass frit, an organic binder, and a solvent, and
coating the composition on a screen mask with an organic layer followed by drying and firing the composition,
wherein a difference of water contact angles of the composition and the screen mask with the organic layer ranges from 40 degrees to 60 degrees.

2. The method of claim 1, wherein the difference of water contact angles of the composition and the screen mask with the organic layer ranges from 50 degrees to 55 degrees.

3. The method of claim 1, wherein a water contact angle of the composition is less than or equal to 30 degrees.

4. The method of claim 1, wherein a water contact angle of the screen mask with the organic layer is greater than or equal to 70 degrees.

5. The method of claim 1, wherein the composition includes 60 to 95 wt % of the conductive powder; 0.5 to 20 wt % of the glass frit; 1 to 20 wt % of the organic binder; and a balance amount of the solvent.

6. The method of claim 1, wherein the organic binder includes a (meth)acrylate-based resin or a cellulose-based resin.

7. An electrode manufactured using the method of claim 1.

8. A solar cell comprising the electrode of claim 7.
